(19) United States
(12) Patent Application Publication
(10) Pub. No.: US 2007/0171705 A1
(43) Pub. Date: Jul. 26, 2007

(54) Writing phase change memories

(76) Inventor: Ward D. Parkinson, Boise, ID (US)

Correspondence Address: TROP PRUNER & HU, PC, 1616 S. VOSS ROAD, SUITE 750, HOUSTON, TX, 77057-2631, US

(21) Appl. No.: 11/300,819

(22) Filed: Dec. 15, 2005

(51) Int. Cl. G11C 11/00

(52) U.S. Cl. 365/163

(57) ABSTRACT

In accordance with some embodiments, the endurance of phase change memory cells may be increased. This increase may be accomplished with adequate margin by reducing the current used to write the reset state. Generally, that current will be a current less than the saturated current.

### BACKGROUND

This invention relates generally to semiconductor memories.

Phase change memory devices use phase change materials, i.e., materials that may be electrically switched between a generally amorphous and a generally crystalline state, as an electronic memory. One type of memory element utilizes a phase change material that may be, in one application, electrically switched between generally amorphous and generally crystalline local orders or between different detectable states of local order across the entire spectrum between completely amorphous and completely crystalline states.

Typical materials suitable for such an application include various chalcogenide elements. The state of the phase change materials is also non-volatile, absent application of excess temperatures, such as those in excess of 150° C. for extended times. When the memory is set in either a crystalline, semi-crystalline, amorphous, or semi-amorphous state representing a resistance value, that value is retained until reprogrammed, even if power is removed. This is because the programmed value represents a phase or physical state of the material (e.g., crystalline or amorphous).

The memory cells can be selected for a reading operation, for example, by applying suitable voltages to the respective word lines and suitable current pulses to the respective bit lines. A voltage reached at the bit line depends on the resistance of the storage element, i.e., the logic value stored in the selected memory cell.

Generally, write currents in the saturation region of the phase change memory element are used to ensure adequate margin. For example, write currents 1.3 times the saturated current may be used. Generally, the highest possible reset state with some overdrive is the goal of the reset bit write operation. The reset bit is the higher resistance state and the set bit is the lower resistance state.

The endurance of a phase change memory element is a function of the magnitude of the write current. Generally, the higher the write current, the lower the endurance of the programmed cell.

### BRIEF DESCRIPTION OF THE DRAWINGS

FIG. 1 is a circuit diagram for one embodiment of the present invention;

FIG. 2 is a hypothetical graph of the log of read resistance after write versus pulsed write current amplitude, with a pulse width greater than 200 nanoseconds and trailing edge less than 10 nsec, in accordance with one embodiment of the present invention;

FIG. 3A is a hypothetical graph of applied current versus time for a set bit in accordance with one embodiment of the present invention;

FIG. 3B is a hypothetical graph of applied current versus time for a reset bit in accordance with one embodiment of the present invention;

FIG. 4A is a hypothetical graph of applied current versus time for a set bit in accordance with another embodiment of the present invention;

FIG. 4B is a hypothetical graph of applied current versus time for a reset bit in accordance with the embodiment of the present invention shown in FIG. 4A; and

FIG. 5 is a system depiction of one embodiment of the present invention.

### DETAILED DESCRIPTION

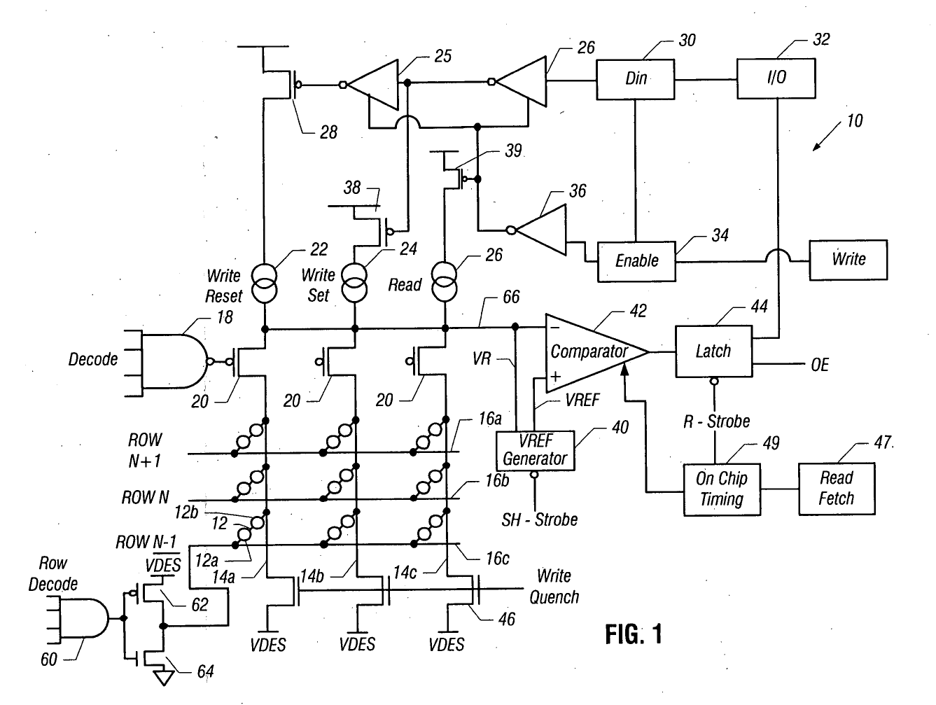

Referring to FIG. 1, a memory 10 may include an array of memory cells 12 arranged in rows 16 and columns 14 in accordance with one embodiment of the present invention. While a relatively small array is illustrated, the present invention is in no way limited to any particular size of an array. While the terms “rows” and “columns” are used herein, they are merely meant to be illustrative and are not limiting with respect to the type and style of the sensed array.

The memory also includes a number of auxiliary lines, useful for the operation thereof. In particular, the memory is provided with a supply voltage line distributing a supply voltage through a chip including the memory, that, depending on the specific memory device embodiment, may be, typically, from 1 to 3 V, for example 1.8 V. A further supply voltage line (such as a ground voltage line GND) distributes the ground voltage or a negative voltage. A high voltage supply line provides a relatively high voltage, generated by devices (e.g. charge-pump voltage boosters not shown) integrated on the same chip, or externally supplied to the memory; for example 4.5-5 V that may, for example, be helpful during write. The lower or higher power supplies may be regulated on or off-chip, such through implementing a band-gap regulator.

The cell 12 may be any memory cell including a phase change memory cell. Examples of phase change memory cells include those using a chalcogenide memory element 12b and a threshold device 12a that may be an ovonic threshold switch (OTS). A select or threshold device is an ovonic threshold switch that can be made of an alloy of chalcogenide that does not switch from an amorphous to a crystalline phase and which undergoes a rapid, electric field initiated change in conductivity, a change in conductivity that persists only so long as a holding current through the device is present.

In the case illustrated, a cell 12 includes an access, select, or threshold device 12a, as well as a memory device 12b which stores a bit of data. The threshold device 12a may have a reduced snapback voltage, such as 0.6V, as the difference between the threshold Vth(ots) and holding voltage Vh(ots). In one embodiment, that snapback voltage of the threshold device 12a (such as an OTS device) is less than the minimum threshold voltage of the memory element 12b by a reasonable margin that is adequate for reading with good margin a reset bit state without the voltage across the sensing device 12b exceeding its threshold voltage when the select device 12a thresholds (triggers after the current exceeds Ithreshold). Upon thresholding, the voltage across 12a snaps back from Vth (threshold voltage) to Vh (holding voltage), a difference that may be less than Vth(oum) of the memory element 12b. In the alternative, the select device may be a transistor or diode using techniques familiar to those reasonably skilled in the art.

In one embodiment, the phase change material used in the sensing memory device 12b may be suitable for non-volatile memory data storage. The phase change material may be a material having electrical properties (e.g., resistance) that may be changed through the application of energy such as, for example, heat, light, voltage potential, or electrical current.

Examples of phase change materials may include a chalcogenide material. A chalcogenide material may be a material that includes at least one element from column VI of the periodic table or may be a material that includes one or more of the chalcogen elements, e.g., any of the elements of tellurium, sulfur, or selenium. Chalcogenide materials may be non-volatile memory materials that may be used to store information that is retained even after the electrical power is removed.

In one embodiment, the phase change material may be chalcogenide element composition from the class of tellurium-germanium-antimony (TeₓGe_{y}Sb_{z}) material or a GeSbTe alloy, such as 2,2,5, although the scope of the present invention is not limited to just these materials.

In one embodiment, if the memory material is a non-volatile, phase change material, the memory material may be programmed into one of at least two memory states by applying an electrical signal to the memory material. An electrical signal may alter the phase of the memory material between a substantially crystalline state and a substantially amorphous state, wherein the electrical resistance of the memory material in the substantially amorphous state is greater than the resistance of the memory material in the substantially crystalline state. Accordingly, in this embodiment, the memory material may be adapted to be altered to a particular one of a number of resistance values within a range of resistance values to provide digital or analog storage of information.

Programming of the memory material to alter the state or phase of the material may be accomplished by applying voltage potentials or forcing current into or out of the selected lines 14, 16, thereby generating a voltage potential across the memory material. An electrical current may flow through a portion of the memory material in response to the applied voltage potentials and current forced, and may result in heating of the memory material.

Altering the phase or state of the memory material may alter an electrical characteristic of the memory material. For example, resistance of the material may be altered by altering the phase of the memory material. Either all or a portion of the phase change memory material may be altered during the writing pulse (i.e. only a portion/region of sensing device 12b adjacent to either the top or bottom electrode may be phase changed during the write operation). In one embodiment, primarily the portion of memory material that undergoes phase change is the region that is adjacent to the smaller, more resistive lower electrode. The memory material may also be referred to as a programmable resistive material or simply a programmable resistance material.

In one embodiment, a voltage pulse may be applied across the memory material by applying about 0 volts to a lower line (e.g., a row 16) and forcing a current into the upper line (e.g., a column 14), so that more than Vh+Iprogram×dv/di, e.g. 1 V, develops across the memory element 12b after the select element 12a (in FIG. 1) is activated or triggered into a low impedance state. A current flowing through the memory material in response to the applied voltage potentials may result in heating of the memory material. This heating and subsequent cooling may alter the memory state or phase of the material.

In a “reset” state, the memory material may be in an amorphous or semi-amorphous state. In a “set” state, the memory material may be in a crystalline or semi-crystalline state. The resistance of the memory material in the amorphous or semi-amorphous state may be greater than the resistance of the material in the crystalline or semi-crystalline state. The association of reset and set with amorphous and crystalline states, respectively, is a convention. Other conventions may be adopted, such as referring to a reset or higher resistance bit state as a logic “0” and a set or lower resistance bit state as a logic “1.”

Due to electrical current, the memory material may be heated to a relatively higher temperature and then subsequently cooled at a fast rate to amorphisize memory material and “reset” memory material, such as by using the quench transistors 46 in FIG. 1 to terminate the programming pulse trailing edge in, e.g. less than 10 nsec. Heating the volume or memory material to a relatively lower crystallization temperature may crystallize and “set” the memory material, using a lower current or a slower trailing edge, e.g greater than 100 nsec.

Various resistances of memory material may be achieved to store information by varying the amount of current flow and duration through the volume of memory material, or by tailoring the edge rate of the trailing edge of the programming current or voltage difference pulse from column to row (that may impact the cooling quench rate of the selected memory element). For example, a slow trailing edge which may be more than 100 nsec will tend to assist setting a bit, whereas a trailing edge rate that may be less than 10 nsec fall time will tend to reset a bit.

The information stored in memory material may be read by measuring the resistance of the memory material. As an example, a read current may be provided to the memory material using opposed lines 14, 16 and a resulting read voltage across the memory material may be compared against a reference voltage using, for example, the sense amplifier 42. The read voltage may be proportional to the resistance exhibited by the selected memory storage device 12b.

In a low voltage or low field regime, the device 12a is off and may exhibit very high resistance in some embodiments. The off resistance can, for example, range from 50,000 ohms to greater than 10 gigaohms at a bias of half the threshold voltage. The device 12a may remain in its off state until exceeding a threshold voltage or until a current greater than threshold current switches the device 12a to a highly conductive, low resistance on state. The voltage across the device 12a after turn on drops to a slightly lower voltage, called the holding voltage V_{HOTS} and remains very close to this holding voltage almost regardless of current flowing, since the dynamic resistance is low, frequently less than 1000 ohms (now in series with its holding voltage). In one embodiment of the present invention, as an example, the threshold voltage of the device 12a may be on the order of 3 volts and the holding voltage may be on the order of 2.5V volts, where the difference may be less than the threshold voltage of the memory storage material, Vthoum.

After passing through the snapback region, in the on state, the device 12a voltage drop remains close to the holding voltage as the current passing through the device is increased, even if up to a relatively high, current level. Above that current level, the device remains on but displays a finite differential resistance with the voltage drop increasing with increasing current. The device 12a may remain on until the current through the device 12a is reduced below a characteristic holding current value that is dependent on the area of the material and the holding voltage may be affected by the choice of top and bottom electrodes utilized to form the device 12a.

The snapback voltage of the device 12a may be reduced to be less than the threshold voltage of the memory element 12b, Vthoum, to avoid triggering a reset bit as it is selected, such as by raising the column 14 and lowering the row 16. The snapback voltage is the threshold voltage minus the holding voltage of the threshold device 12a. The threshold voltage is where the dynamic resistance of the device switches from high to low. In one embodiment, the snapback voltage of the device 12a of about 0.5V is less than half the minimum threshold voltage of the memory element 12b of about 1V. In another embodiment, the snapback voltage is less than the minimum threshold voltage of the element 12b minus about 600 mV. If necessary to improve margin against triggering a reset bit, the reset bit current used may be increased on-chip above the minimum necessary reset current to increase the 12b memory element threshold voltage, thus improving margin against triggering the reset memory bit(s) during read. For example, if during operation of the memory in the field, excessive error correcting (Hamming) code (ECC) errors are detected, the write current may be increased in increments of, for example, 10% until ECC errors are reduced.

Or, the reference voltage used for read may be indexed up. Then, after writing a bit to the reset date, the bit may be read to confirm that the bit does not threshold. If instead, the bit thresholds, the reset current may be increased some amount, such as 10%, and the bit rewritten until it can be read with the higher reference voltage without thresholding. Current may be increased in 10% increments until some upper limit is reached (such as 2×normal programming current), and then if still unsuccessful then bit or block may be logged as bad and not used thereafter. For another rewrite cycle, another bit may be used with a transposed address. Or the block may be rewritten to another block, using for either approach techniques which are familiar to those skilled in the art.

The snapback voltage of the threshold element (OTS) 12a may be reduced by reducing the threshold voltage and/or increasing the holding voltage. The threshold voltage may be reduced, for example, by reducing the thickness of the switching material, and/or altering its composition. The holding voltage may be increased, for example, by changing the type or composition of electrodes that apply a potential across the switching material. Or, for example, to obtain Vth at a high voltage with reduced Vsnapback, Vh may be increased by placing several lower Vth select devices 12a in series within the memory cell.

In some embodiments of the present invention, the threshold device 12a does not change phase. It remains permanently amorphous and its current-voltage characteristics may remain about the same throughout its operating life.

As an example, for a 0.5 micrometer diameter device 12a formed of TeAsGeSSe having respective atomic percents of 16/13/15/1/55, the holding current may be on the order of 0.1 to 1 micro-amps (uA) in one embodiment. Below this holding current, the device 12a turns off and returns to the high resistance regime at low voltage, low field applied. The threshold current for the device 12a may generally be of the same order as the holding current or greater, e.g. 10 ua, to avoid oscillations during read. The holding current may be altered by changing process variables, such as the top and bottom electrode material and the chalcogenide material, and/or the contact area between the electrodes and chalcogenide. The device 12a may provide high “on current” for a given area of device compared to conventional access devices such as metal oxide semiconductor field effect transistors or bipolar junction transistors or semiconductor diodes. However, such devices may also be used in some embodiments, as shall be apparent to one skilled in the art as an adaptation of the embodiments and descriptions herein.

A decoder 18 in FIG. 1 receives address signals to select the desired column using transistors 20 uniquely associated with each column for cell selection. A reset write current source 22 is coupled to node 66 in parallel with a set write current source 24 and a read current source 26. The read current may exceed the threshold current of the memory element 12b and be set to generate a fast rise time on the selected column (14a or 14b or 14c, with selection determined by the “on” select transistors 20a or 20b or 20c). The current sources are coupled to selected columns as needed in response to addressing commands from an external memory user such as a processor. A set of transistors 46a or 46b or 46c may be located on the bottom of the columns 14 in order to enable write quenching and deselect by assuring fast write current pulse trailing edge on columns 14. Fast quench is also assisted by simultaneous switching of the row from select to deselect voltage. Alternately instead of a read current source, a voltage may be forced which is about equal to VREF and the compliance limited to the read current which does not rewrite the bit (here for example, 50 ua). Then, if the current driven after the transient dies out is greater than Iread, the bit is set. Otherwise, the bit is reset. By such techniques, the current forced can be greater than Ith(oum) of 12b, yet the device is not thresholded.

Transistors 28, 38, and 39 are on/off switches that select the desired current, generated by current source 22, 24 or 26, to the selected column 14 depending on whether the function desired respectively is to write a bit to its reset state, or write to the set state, or read the selected bit. A gate 36 either disables read by enabling write Din gates, or turns on transistor 36 to enable the read current source 26. Unless enabled, gates 25 and 26 turn off the write current sources, 22 and 24. The gate 36 is controlled by enable circuit 34. An input/output (I/O) control 32 is coupled to the data in (Din) circuit 30, which is coupled to select either write 0 or write 1 through selection of either current source 22 or 24, one having less write current to write a 1 (and crystallize) than the other that resets the selected bit to a 0 (amorphous). The Data-in circuit 30 is write enabled by 34 through gate 36. This set of write devices may be increased or tailored (and the number reduced to one) to write more than two levels in the cell.

A sense amplifier 42 in FIG. 1, in the form of a comparator in one embodiment, receives one input from a selected column, for example 14c, being read. The sense amplifier 42 may optionally include a pre-charge circuit to pre-charge node 66 and the selected column of columns 14a, b or c to a pre-charged voltage by means apparent to one reasonably skilled in the art.

The sense amplifier 42 and reference voltage generator 40, which may force a voltage that stays relatively fixed during the read cycle, may be provided on each column 14 in one embodiment to read one or more columns in parallel, or may be selectively applied, by decoding through decoder 18 and column select transistors 20, to one or more column lines.

The on-chip timing 49 for the sense amplifier 42 and data output latch 44 may provide an output enable (OE) signal as an option which at least indicates when the output can be driven, though as commonly done in the industry, OE is also furnished by the processor to enable the output driver to a low impedance state (once the data is ready from the read cycle) to avoid bus conflict such as to and from the processor if Din is on the same pin as Dout.

The output signal from the latch 44 is controlled by a read (R) strobe in that the whole read fetch cycle is started by the equivalent of a read signal, again usually furnished by a processor. Alternatively, this signal may be generated on-chip by sensing an address change when write is not selected.

The reference generator 40 produces a reference voltage VREF which may be higher than a column voltage driven by a set bit but lower in voltage than a column driven by a reset bit, a column voltage that may be clamped or limited to force across the memory element 12b less than the threshold voltage, and the voltage clamp may preferably be lower than this voltage for margin, such as by 0.5V. The set state corresponds to a lower resistance value and the reset state corresponds to a higher resistance value. Approximately, VREF may be set at the voltage on the selected column 14 above the holding voltage of the device 12a (e.g., about 2.5V) plus two-thirds of the approximately 1V threshold voltage of the device 12b, for a total of about 3.2V, to provide reasonable margin between the one and zero states of the cell.

However, here the set bit may be detected indirectly. A reset bit has a high resistance times a relatively high read current such as 50 microAmps, so if allowed to charge indefinitely, the voltage across the device 12b alone would be 5V or greater for a 100K or greater reset bit. However, once the column of the reset bit exceeds VREF, the current is turned off, stopping further charging to avoid triggering the reset bit. This also signals that the bit is a zero (reset), which is latched and sent to the output.

In accordance with some embodiments of the present invention, the set state is written optimally to the lowest possible resistance state. However, instead of writing to the highest possible reset state with some overdrive, the reset bit may, instead, be written to be only a necessary differential resistance greater than the set state. This may result in reduced write current and increased endurance. In one embodiment, a relatively fast trailing edge may be used for the reset bit, while retaining the slow trailing edge for writing the set bit.

For example, referring to FIG. 3A, the set bit may be written at an applied current pulse whose trailing edge trails off rather than abruptly decreasing. Conversely, the reset bit may include an abrupt leading and trailing edge and may have a slightly longer duration or higher amplitude relative to writing a set bit.

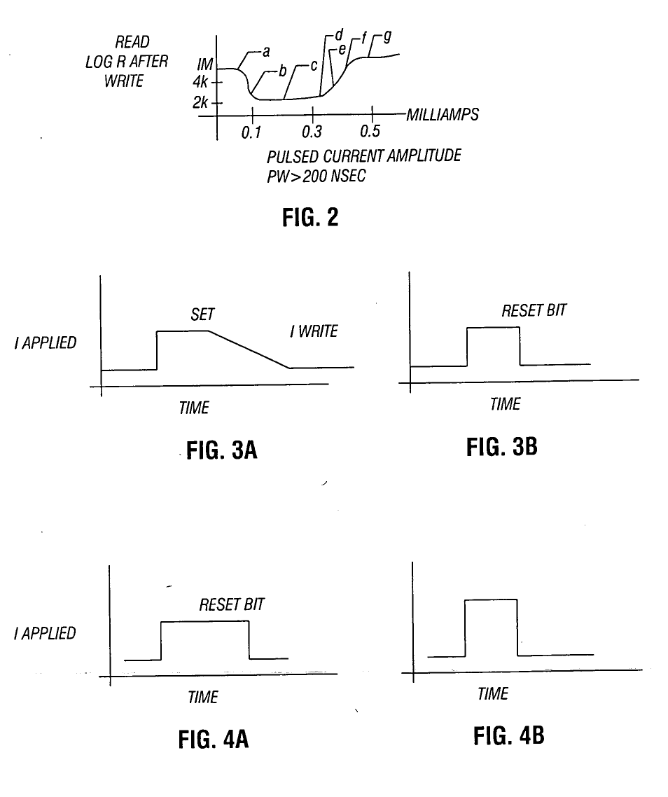

Referring to FIG. 2, the resistance that results from different write pulse magnitudes is illustrated. While certain current amplitudes in milliamps are provided and certain resistances in ohms are provided, those skilled in the art will appreciate that these numbers are only for illustration purposes. The point of the graph is to illustrate the saturation region which begins after the point F and is represented by the point G. Conventionally, reset bits have been written using currents above G to provide improved margin. Set bits have traditionally been programmed at or about the point C. The point C is the region where increasing current amplitude does not decrease the resistance of the bit. Similarly, in the saturation region G, increasing the write current amplitude does not significantly increase the resulting resistance of the programmed bit.

A write pulse greater than 0.5 milliamps, indicated by the point F, writes a reset, high resistance state that may, in some embodiments, be greater than 100,000 ohms. To allow for variation in the bit, the actual write current may be 1.5 milliamps to assure each bit is saturated to maximize margin.

Similarly, a bit may be written to the set state having a resistance on the order of about 10,000 ohms from either set or reset state by forcing about half the reset current, or less than the current where the bit starts to increase in resistance, such as 0.25 milliamps.

The point A is where the current pulse does not change the state of a set or reset bit, a current that may be used for reading the bit. The point B is where the current lowers the bit resistance. The point C is the substantially flat region where changes in write current do not significantly change the resulting set bit resistance. The point D is at the edge of the reset bit onset where the bit resistance changes to higher resistance. Point D is where the substantially flat region ends and increases in current begin to produce higher resistance. Point E is where the set resistance is changed significantly, such as by more than two times, compared to the relatively lower resistance at the point C. The point F is where the reset resistance stops increasing rapidly as a function of increased write current amplitude. The point G is where the reset bit is saturated and increases very slowly in resistance for increased current amplitude.

Thus, in one embodiment of the present invention, a set bit may be written using a slow trailing edge and a reset bit may be written using a fast trailing edge (FIGS. 3A and 3B). Alternatively, as shown in FIGS. 4A and 4B, both the reset and set bits may have fast trailing edges and about the same width, but the reset bit may have a significantly higher applied current than the set bit. The width and amplitude may be set to minimize the set resistance, and then the current increased for reset compared to set.

A set current at point B may be used instead of set current at the point C if the trailing edge is fast as shown in FIG. 4A. A reset current at point E or F, or in between E and F may be chosen for writing a reset bit. This reset current does not produce the higher saturated resistance, but results in a resistance that is two times that of the resistance achieved at point C. Hence, instead of a dynamic range of ten to one or greater for reset, compared to a set bit, the dynamic range may be two to one or less in some embodiments.

For more margin, a reset current from E to F may be chosen. The trailing edge may be set to be fast, such as less than ten nanoseconds for reset and slower than 100 nanoseconds, for example 200 nanoseconds, for a set bit. As a result, the reset resistance is greater than two times that of the set bit resistance, using the same amplitude, with a difference in resistance for reset state resulting from the trailing edge choice.

However, in general, it may be that the reset resistance is chosen to be less than five times the set resistance in accordance with some embodiments of the present invention. In general, the reset memory element is programmed in the range E to F with a current less than the saturated current of the memory element (point G).

With lower write current and the resulting improved endurance, the drift of the reset current may also be reduced. However, this drift is a function of the number of cycles seen by any given bit. If the drift after use in the field is towards less current to achieve the same resistance, then leaving the current fixed results in more overdrive, moving from point F towards point G in FIG. 2 for that bit. Hence, that bit writes to a higher resistance but its endurance decreases.

However, statistically only a portion of the population of bits in the array see the reduced endurance since few of the bits see the allowed number of cycles permitted by the memory specification. Hence, while improved endurance is not assured, improved endurance will typically be the case. Meanwhile, programming may be achieved at lower currents with improved array efficiency because of the reduced driver size and the reduced power consumption per write cycle, resulting in better battery life in some battery powered embodiments. When implemented in a system, the reduced reset programming current results in less power drain.

While an embodiment with two states is illustrated, four states can be created by creating four levels in which the highest resistance level is still about that level corresponding to the point F in FIG. 2, improving current and endurance.

In some embodiments at probe test, bits can be scanned for a block of memory and the current defined for set that centers all of the bits and their variations over time and temperature. This current could, for example, be entered in fuses, such as laser written fuses. Similarly, the reset current could be written in such fuses to effectively program the set and reset currents for that particular integrated circuit.

Using feedback, the reset current may be tailored for each bit so that the reset resistance is about two times that of the set bit. For example, if the set bit resistance may be a minimum at a set current of about 0.2 milliamps and the resulting set bit resistance is about 5,000 ohms, the reset current may be 0.4 milliamps, resulting in a reset resistance of 25,000 ohms. With feedback, such as write, then read, then rewrite, the bit may be rewritten to 10,000 ohms by iterating a current resulting in that resistance, such as with 0.3 milliamps. However, since the resistance is higher than needed, the bit could be left in that state, since nothing is improved by rewriting.

Similarly, if the bit is reset but the resistance is 8,000 ohms, where 10,000 ohms is the minimum, the bit can be rewritten with more current, increasing the current for repeated writes until the bit resistance is greater than 10,000 ohms. If the bit resistance is greater than 10,000 ohms, more current may be used, but with a slower edge rate, increasing the edge rate from 100 nanoseconds to one microsecond, if necessary, to adequately reduce the set resistance.

In some embodiments, additional write current sources in the form of p-channel transistors may be used or the gate of the current source transistor 38 may be modulated appropriately to achieve the results described herein.

In a multi-bit scheme for physical cells, multiple reference voltages can be created in a similar fashion. Writing varying resistance levels to a given cell may allow more than one bit per cell using techniques apparent to those skilled in the art, though the techniques described herein are for one bit per cell. For example, VREF1, and an additional VREF2 and VREF3 may be created and appropriately adjusted to allow sensing four different resistance ranges—thus storing two or more logical bits in one physical cell. By such techniques, more or less levels or bits may be stored and sensed in a physical cell, including through use of feedback/rewrite such as with a binary search.

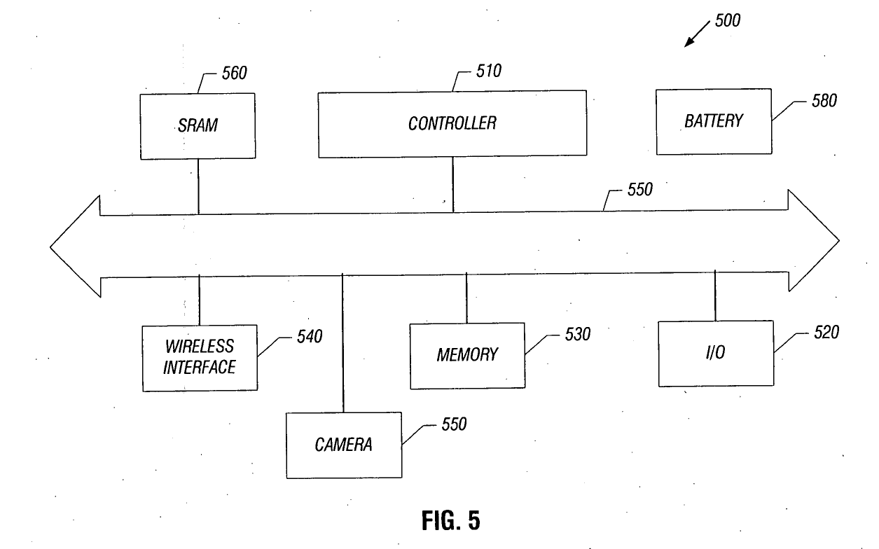

Turning to FIG. 5, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wireessly. System 500 may be used in any of the following systems: a wireless local area network (WLAN) system, a wireless personal area network (WPAN) system, or a cellular network, although the scope of the present invention is not limited in this respect.

System 500 may include a controller 510, an input/output (I/O) device 520 (e.g. a keypad, display), a memory 530, a wireless interface 540, a digital camera 550, and a static random access memory (SRAM) 560 and coupled to each other via a bus 550. A battery 580 may supply power to the system 500 in one embodiment. It should be noted that the scope of the present invention is not limited to embodiments having any or all of these components.

Controller 510 may comprise, for example, one or more microprocessors, digital signal processors, micro-controllers, or the like. Memory 530 may be used to store messages transmitted to or by system 500. Memory 530 may also optionally be used to store instructions that are executed by controller 510 during the operation of system 500, and may be used to store user data. The instructions may be stored as digital information and the user data, as disclosed herein, may be stored in one section of the memory as digital data and in another section as analog memory. As another example, a given section at one time may be labeled as such and store digital information, and then later may be relabeled and reconfigured to store analog information. Memory 530 may be provided by one or more different types of memory. For example, memory 530 may comprise a volatile memory (any type of random access memory), a non-volatile memory such as a flash memory, and/or memory 10 illustrated in FIG. 1.

The I/O device 520 may be used to generate a message.

The system 500 may use the wireless interface 540 to transmit and receive messages to and from a wireless communication network with a radio frequency (RF) signal. Examples of the wireless interface 540 may include an antenna, or a wireless transceiver, such as a dipole antenna, although the scope of the present invention is not limited in this respect. Also, the I/O device 520 may deliver a voltage reflecting what is stored as either a digital output (if digital information was stored), or it may be analog information (if analog information was stored).

While an example in a wireless application is provided above, embodiments of the present invention may also be used in non-wireless applications as well.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. a method comprising:
programming a phase change memory element to the reset state with a current less than the saturated current of the memory element.

2. The method of claim 1 including programming a reset bit with an abrupt trailing edge.

3. The method of claim 1 including programming a set bit with a gradual trailing edge.

4. The method of claim 1 including programming a set bit with an abrupt trailing edge.

5. The method of claim 1 including programming a reset bit to a resistance of about two times the resistance of a set bit.

6. The method of claim 1 including programming a reset bit with a resistance less than five times the resistance of the set bit.

7. The method of claim 1 including using a trailing edge to write a reset bit that is less than ten nanoseconds and having a trailing edge slower than 100 nanoseconds for writing a set bit.

8. The method of claim 1 including using feedback to tailor the resistance for said bits.

9. The method of claim 8 including adjusting the trailing edge rate to tailor the resistance of a reset bit.

10. The method of claim 1 including programming a reset bit with a current between saturation and the current where the reset resistance is at least two times compared to the relatively lower set resistance at the region where changing write current does not significantly change the resulting set bit resistance.

11. The method of claim 10 including programming a reset bit to a resistance lower than the point where the resistance stops increasing rapidly as a function of increased write current amplitude.

12. The method of claim 1 including programming a set bit at a point where increasing current lowers the resistance prior to the substantially flat region wherein changes in write current do not significantly change the resulting set bit resistance.

13. A phase change memory comprising:
a read circuit; and
a write circuit to program a reset bit with a current less than the saturated current of the memory element.

14. The memory of claim 13 wherein said write circuit to program the reset bit with an abrupt trailing edge.

15. The memory of claim 13, said write circuit to program a set bit with a gradual trailing edge.

16. The memory of claim 13, said write circuit to program a set bit with an abrupt trailing edge.

17. The memory of claim 13, said write circuit to program a reset bit to resistance of about two times the resistance of a set bit.

18. The memory of claim 13, said write circuit to program a reset bit with a resistance less than five time the resistance of a set bit.

19. A system comprising:
a processor;
a battery coupled to said processor; and
a memory including an array of phase change memory cells and a write circuit to program a cell using a current less than the saturated current of the cell.

20. The system of claim 19 wherein said cell includes a nonprogrammable, chalcogenide select device coupled in series to a chalcogenide memory element.

21. The system of claim 19 wherein said write circuit to program a reset bit to a resistance less than five times the resistance of a set bit.

22. The system of claim 21 wherein said write circuit to program a reset bit to a resistance of about twice the set bit resistance.

23. The system of claim 21 wherein said write circuit to program a reset bit using a current in a region where resistnace increases more rapidly with increasing current than the resistance increases in saturation.

24. The system of claim 19 including a camera.

25. The system of claim 19 including a camera where information is stored on a memory wherein cell state is determined by a rate detector.
